(19) United States
(12) Patent Application Publication
(10) Pub. No.: US 2014/0367816 A1
(43) Pub. Date: Dec. 18, 2014

(54) PHOTODETECTOR DEVICE HAVING LIGHT-COLLECTING OPTICAL MICROSTRUCTURE

(71) Applicant: Avago Technologies General IP (Singapore) Pte.Ltd., Singapore (SG)

(72) Inventors: Ramana M.V. Murty, Sunnyvale, CA (US); Tak Kui Wang, Cupertino, CA (US); David G. McIntyre, Singapore (SG); Ye Chen, San Jose, CA (US)

(21) Appl. No.: 13/915,849

(22) Filed: Jun. 12, 2013

(51) Int. Cl. H01L 31/0232

(52) U.S. Cl. CPC H01L 31/02327
USPC 257/432

(57) ABSTRACT

A opto-electronic device includes a semiconductor device and a non-imaging optical concentrator on a surface of the semiconductor device. The semiconductor device has a substrate and a photodetector formed on a surface of the substrate. The non-imaging optical concentrator has a peripheral surface extending around a central region of the active area of the photodetector. The non-imaging optical concentrator redirects at least a portion of incoming light into the active area.

### BACKGROUND

Optical data communication systems commonly include optical receiver devices that receive optical signals conveyed via an optical communication link (e.g., optical fiber) and convert the optical signals into electrical signals. In this manner, the data or information contained in the optical signals can be recovered or received and provided to other electronic systems, such as switching systems or processing systems. Such optical receiver devices include photodetectors, such as photodiodes. A common type of photodiode used in optical receiver devices is known as a PIN photodiode due to its structure comprising an intrinsic or lightly doped semiconductor layer sandwiched between a P-type semiconductor layer and an N-type semiconductor layer. PIN diode physics dictate that the size of the active area (i.e., photosensitive area) is inversely proportional to the maximum data rate that the device can detect. Thus, a PIN photodiode suitable for high data rates must have a small active area. However, the light emitted by an optical fiber forms a beam that is relatively wide compared with the width of a high-speed PIN photodiode. Focusing or otherwise directing the incoming light (optical signals) onto a very small PIN photodiode poses design challenges.

An optical receiver can include a lens between a PIN photodiode device and an end of an optical fiber to focus light emitted from the fiber onto the PIN photodiode. However, including such a lens in an optical receiver can impact ease of assembly and thus manufacturing economy. It has also been suggested to fashion a region of the semiconductor substrate from which the PIN photodiode is formed into a reflector that directs light into the active area of a PIN photodiode from a lateral direction, i.e., parallel to the plane of the substrate. However, such a structure is difficult to fabricate and thus impacts manufacturing economy. Moreover, such a structure is generally incapable of increasing the light-collecting area of the PIN photodiode device by more than a few microns.

It would be desirable to provide a photodetector device that has a large collection area relative to the size of the active area and that can be readily manufactured.

### SUMMARY

Embodiments of the present invention relate to an opto-electronic device and the method by which it operates to concentrate incoming light upon a photodetector. In an exemplary embodiment, the opto-electronic device comprises a semiconductor device and a non-imaging optical concentrator on a surface of the semiconductor device. The semiconductor device has a substrate and a photodetector formed on a surface of the substrate. The non-imaging optical concentrator has a peripheral surface extending around a central region of the active area of the photodetector. The non-imaging optical concentrator redirects at least a portion of incoming light into the active area.

Other systems, methods, features, and advantages will be or become apparent to one with skill in the art upon examination of the following figures and detailed description. It is intended that all such additional systems, methods, features, and advantages be included within this description, be within the scope of the specification, and be protected by the accompanying claims.

### BRIEF DESCRIPTION OF THE DRAWINGS

The invention can be better understood with reference to the following drawings. The components in the drawings are not necessarily to scale, emphasis instead being placed upon clearly illustrating the principles of the present invention.

FIG. 1 is a top plan view of an opto-electronic device, in accordance with a first exemplary embodiment of the invention.

FIG. 2 is a sectional view taken along line 2-2 of FIG. 1.

FIG. 3 is a top plan view of another opto-electronic device, in accordance with a second exemplary embodiment of the invention.

FIG. 4 is a sectional view taken along line 4-4 of FIG. 3.

FIG. 5 is a top plan view of yet another opto-electronic device, in accordance with a third exemplary embodiment of the invention.

FIG. 6 is a sectional view taken along line 6-6 of FIG. 5.

FIG. 7 is a top plan view of still another opto-electronic device, in accordance with a fourth exemplary embodiment of the invention.

FIG. 8 is a sectional view taken along line 8-8 of FIG. 7.

FIG. 9 is a top plan view illustrating a first step of an exemplary method for making the exemplary opto-electronic device of FIGS. 1-2.

FIG. 10 is a sectional view taken along line 10-10 of FIG. 9.

FIG. 11 is a top plan view illustrating a second step of an exemplary method for making the exemplary opto-electronic device of FIGS. 1-2.

FIG. 12 is a sectional view taken along line 12-12 of FIG. 11.

FIG. 13 is a top plan view illustrating a third step of an exemplary method for making the exemplary opto-electronic device of FIGS. 1-2.

FIG. 14 is a sectional view taken along line 14-14 of FIG. 13.

FIG. 15 is a top plan view illustrating a fourth step of an exemplary method for making the exemplary opto-electronic device of FIGS. 1-2.

FIG. 16 is a sectional view taken along line 16-16 of FIG. 15.

FIG. 17 is a top plan view illustrating a fifth step of an exemplary method for making the exemplary opto-electronic device of FIGS. 1-2.

FIG. 18 is a sectional view taken along line 18-18 of FIG. 17.

FIG. 19 is a top plan view illustrating a sixth step of an exemplary method for making the exemplary opto-electronic device of FIGS. 1-2.

FIG. 20 is a sectional view taken along line 20-20 of FIG. 19.

FIG. 21 is a top plan view illustrating a seventh step of an exemplary method for making the exemplary opto-electronic device of FIGS. 1-2.

FIG. 22 is a sectional view taken along line 22-22 of FIG. 21.

FIG. 23 is a top plan view illustrating an eighth step of an exemplary method for making the exemplary opto-electronic device of FIGS. 1-2.

FIG. 24 is a sectional view taken along line 24-24 of FIG. 23.

FIG. 25 is a top plan view illustrating a ninth step of an exemplary method for making the exemplary opto-electronic device of FIGS. 1-2.

FIG. 26 is a sectional view taken along line 26-26 of FIG. 25.

FIG. 27 is a sectional view illustrating a tenth step of an exemplary method for making the exemplary opto-electronic device of FIGS. 1-2.

FIG. 28 is a sectional view illustrating an eleventh step of an exemplary method for making the exemplary opto-electronic device of FIGS. 1-2.

FIG. 29 is a sectional view illustrating a twelfth step of an exemplary method for making the exemplary opto-electronic device of FIGS. 1-2.

FIG. 30 is a top plan view illustrating a first step of an exemplary method for making the exemplary opto-electronic device of FIGS. 5-6.

FIG. 31 is a sectional view taken along line 31-31 of FIG. 30.

FIG. 32 is a top plan view illustrating a second step of an exemplary method for making the exemplary opto-electronic device of FIGS. 5-6.

FIG. 33 is a sectional view taken along line 33-33 of FIG. 32.

FIG. 34 is a top plan view illustrating a third step of an exemplary method for making the exemplary opto-electronic device of FIGS. 5-6.

FIG. 35 is a sectional view taken along line 35-35 of FIG. 34.

FIG. 36 is a top plan view illustrating a fourth step of an exemplary method for making the exemplary opto-electronic device of FIGS. 5-6.

FIG. 37 is a sectional view taken along line 37-37 of FIG. 36.

FIG. 38 is a top plan view illustrating a fifth step of an exemplary method for making the exemplary opto-electronic device of FIGS. 5-6.

FIG. 39 is a sectional view taken along line 39-39 of FIG. 38.

FIG. 40 is a top plan view illustrating a sixth step of an exemplary method for making the exemplary opto-electronic device of FIGS. 5-6.

FIG. 41 is a sectional view taken along line 41-41 of FIG. 40.

FIG. 42 is a top plan view illustrating a seventh step of an exemplary method for making the exemplary opto-electronic device of FIGS. 5-6.

FIG. 43 is a sectional view taken along line 43-43 of FIG. 42.

FIG. 44 is a top plan view illustrating an eighth step of an exemplary method for making the exemplary opto-electronic device of FIGS. 5-6.

FIG. 45 is a sectional view taken along line 45-45 of FIG. 44.

FIG. 46 is a top plan view illustrating a ninth step of an exemplary method for making the exemplary opto-electronic device of FIGS. 5-6.

FIG. 47 is a sectional view taken along line 47-47 of FIG. 46.

FIG. 48 is a sectional view illustrating a tenth step of an exemplary method for making the exemplary opto-electronic device of FIGS. 5-6.

FIG. 49 is a sectional view illustrating an eleventh step of an exemplary method for making the exemplary opto-electronic device of FIGS. 5-6.

FIG. 50 is a sectional view illustrating a first step of an exemplary method for making the exemplary opto-electronic device of FIGS. 3-4.

FIG. 51 is a sectional view illustrating a second step of an exemplary method for making the exemplary opto-electronic device of FIGS. 3-4.

FIG. 52 is a sectional view illustrating a third step of an exemplary method for making the exemplary opto-electronic device of FIGS. 3-4.

FIG. 53 is a sectional view illustrating a fourth step of an exemplary method for making the exemplary opto-electronic device of FIGS. 3-4.

FIG. 54 is a sectional view illustrating a fifth step of an exemplary method for making the exemplary opto-electronic device of FIGS. 3-4.

FIG. 55 is a sectional view illustrating a sixth step of an exemplary method for making the exemplary opto-electronic device of FIGS. 3-4.

FIG. 56 is a top plan view illustrating an exemplary method for making the exemplary opto-electronic device of FIGS. 7-8.

FIG. 57 is a sectional view taken along line 57-57 of FIG. 56.

### DETAILED DESCRIPTION

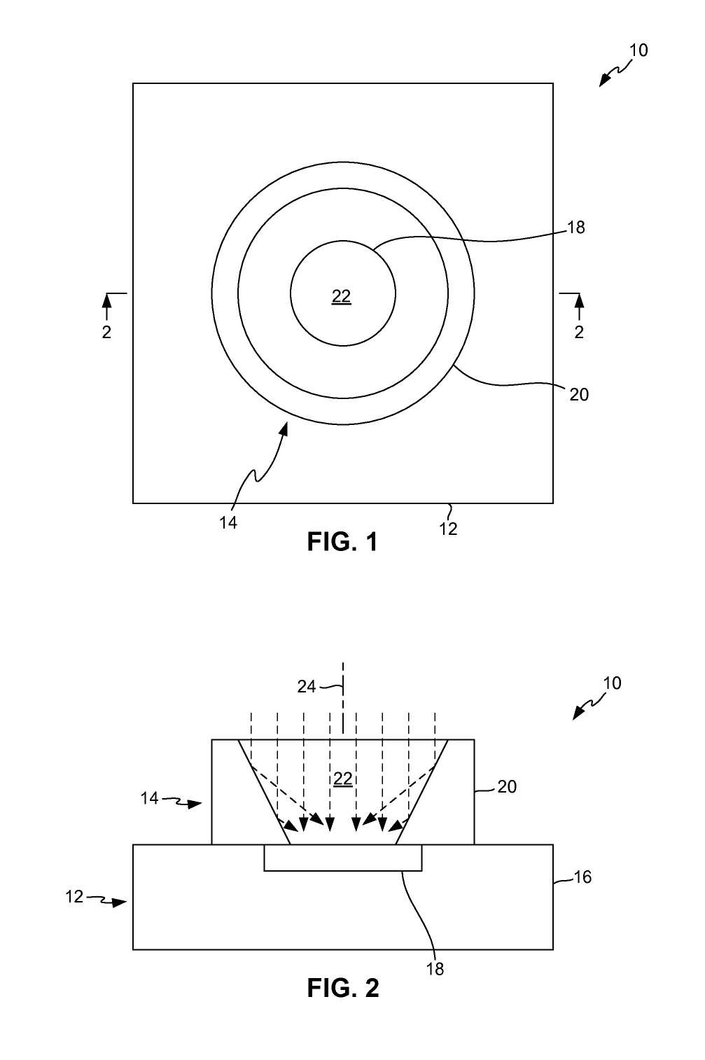

As illustrated in FIGS. 1-2, in a first illustrative or exemplary embodiment of the invention, an opto-electronic device 10 includes a semiconductor device 12 and a non-imaging optical concentrator 14 mounted on the surface of semiconductor device 12. Semiconductor device 12 includes a substrate 16 and a photodetector having an active area 18 formed on the surface of substrate 16.

Non-imaging optical concentrator 14 has a barrel-shaped body 20 with an interior cavity region 22. Cavity region 22 has a frusto-conical or truncated cone shape. That is, cavity region 22 has a circular cross-sectional shape that tapers in diameter (and thus tapers in area) from one end to the other. Cavity region 22 has the largest diameter (i.e., is widest) at the end farthest from active area 18 and has the smallest diameter (i.e., is narrowest) at the end adjacent to active area 18. The longitudinal axis 24 of cavity region 22 is aligned with the optical axis (central region) of active area 18. Cavity region 22 defines a peripheral surface, i.e., a surface that extends around the periphery of the central region of active area 18. The walls of cavity region 22 are coated with a metal film or other layer of optically reflective material. As described below in further detail, non-imaging optical concentrator 14 can be made of a semiconductor material, a photosensitive polymer, or other suitable material.

In operation, light is received at the wide end of cavity region 22. The walls of cavity region 22 (i.e., the peripheral surface) redirect a portion of this incoming light into active area 18 by reflecting the light, as indicated in broken line in FIG. 2.

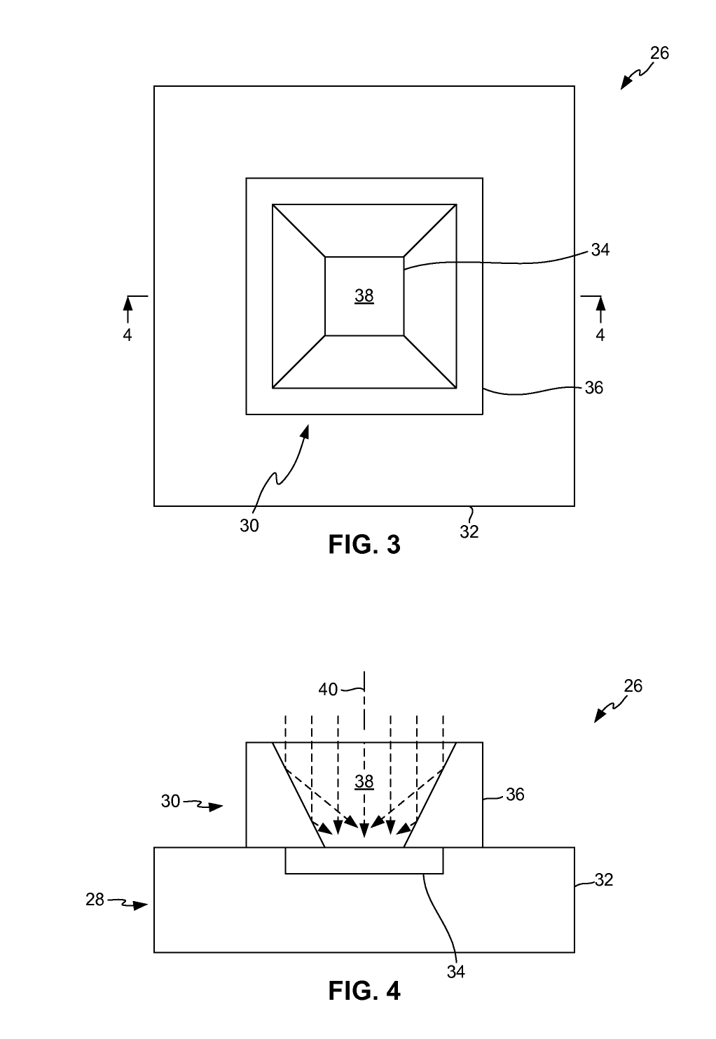

As illustrated in FIGS. 3-4, in a second illustrative or exemplary embodiment of the invention, an opto-electronic device 26 includes a semiconductor device 28 and a non-imaging optical concentrator 30 mounted on the surface of semiconductor device 28. Semiconductor device 28 includes a substrate 32 and a photodetector having an active area 34 formed on the surface of substrate 32.

Non-imaging optical concentrator 30 has a body 36 with a square profile and an interior cavity region 38. Cavity region 38 has a frusto-polyhedral (more specifically, frusto-pyramidal or truncated four-sided pyramidal) shape. That is, cavity region 38 has a polygonal (more specifically, square) cross-sectional shape that tapers in size from one end to the other. Cavity region 38 has the largest cross-section (i.e., each side is longest) at the end farthest from active area 34 and has the smallest cross-section (i.e., each side is shortest) at the end adjacent to active area 34. The longitudinal axis 40 of cavity region 38 is aligned with the optical axis of active area 18. Cavity region 38 defines a peripheral surface, i.e., a surface that extends around the periphery of a central region of active area 34. The walls of cavity region 38 are coated with a metal film or other layer of optically reflective material. As described below in further detail, non-imaging optical concentrator 30 can be made of a semiconductor material, a photosensitive polymer, or other suitable material.

In operation, light is received at the wide end of cavity region 38. The walls of cavity region 38 (i.e., the peripheral surface) redirect a portion of this incoming light into active area 34 by reflecting the light, as indicated in broken line in FIG. 4.

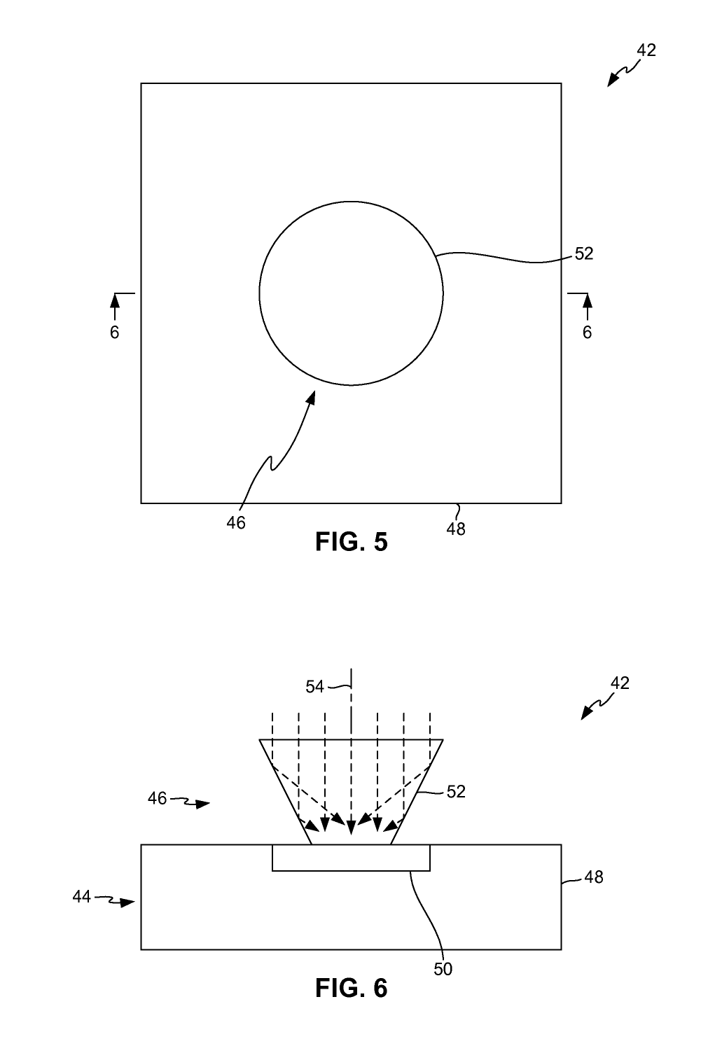

As illustrated in FIGS. 5-6, in a third illustrative or exemplary embodiment of the invention, an opto-electronic device 42 includes a semiconductor device 44 and a non-imaging optical concentrator 46 mounted on the surface of semiconductor device 12. Semiconductor device 44 includes a substrate 48 and a photodetector having an active area 50 formed on the surface of substrate 48.

Non-imaging optical concentrator 46 has a solid region 52. Solid region 52 has a frusto-conical or truncated cone shape. That is, solid region 52 has a circular cross-sectional shape that tapers in diameter (and thus tapers in area) from one end to the other. Solid region 52 has the largest diameter (i.e., is widest) at the end farthest from active area 50 and has the smallest diameter (i.e., is narrowest) at the end adjacent to active area 50. The longitudinal axis 54 of solid region 52 is aligned with the optical axis of active area 50. Solid region 52 defines a peripheral surface, i.e., a surface that extends around the periphery of a central region of active area 50. The peripheral surface is reflective (i.e., total internal reflection (TIR) occurs) because it is the interface between the sidewalls of solid region 52 and the surrounding air. As described below in further detail, non-imaging optical concentrator 46 can be made of a semiconductor material, a photosensitive polymer, or other suitable material.

In operation, light is received at the wide end of solid region 52. The peripheral surface defined by the interface between the sidewalls of solid region 52 and the surrounding air redirects a portion of this incoming light into active area 50 by reflecting the light, as indicated in broken line in FIG. 6.

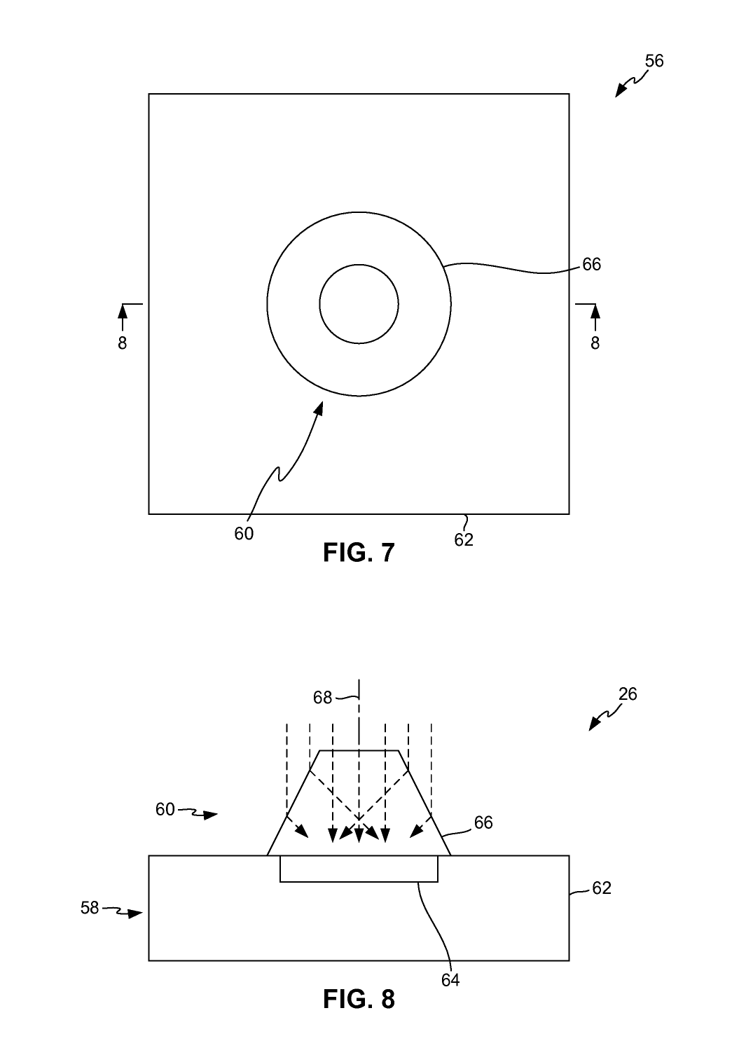

As illustrated in FIGS. 7-8, in a fourth illustrative or exemplary embodiment of the invention, an opto-electronic device 56 includes a semiconductor device 58 and a non-imaging optical concentrator 60 mounted on the surface of semiconductor device 58. Semiconductor device 58 includes a substrate 62 and a photodetector having an active area 64 formed on the surface of substrate 62.

Non-imaging optical concentrator 60 has a solid region 66. Solid region 66 has a frusto-conical or truncated cone shape. That is, solid region 66 has a circular cross-sectional shape that tapers in diameter (and thus tapers in area) from one end to the other. Solid region 66 has the largest diameter (i.e., is widest) at the end adjacent to active area 50 and has the smallest diameter (i.e., is narrowest) at the end farthest from active area 50. The longitudinal axis 68 of solid region 66 is aligned with the optical axis of active area 64. Solid region 66 defines a peripheral surface, i.e., a surface that extends around the periphery of a central region of active area 64. The peripheral surface is refractive because it is the interface between the sidewalls of solid region 66 and the surrounding air. As described below in further detail, non-imaging optical concentrator 60 can be made of a semiconductor material, a photosensitive polymer, or other suitable material.

In operation, light is received through the sidewalls and the narrow end of solid region 66. The peripheral surface defined by the interface between the sidewalls of solid region 66 and the surrounding air redirects a portion of this incoming light into active area 64 by refracting the light, as indicated in broken line in FIG. 8.

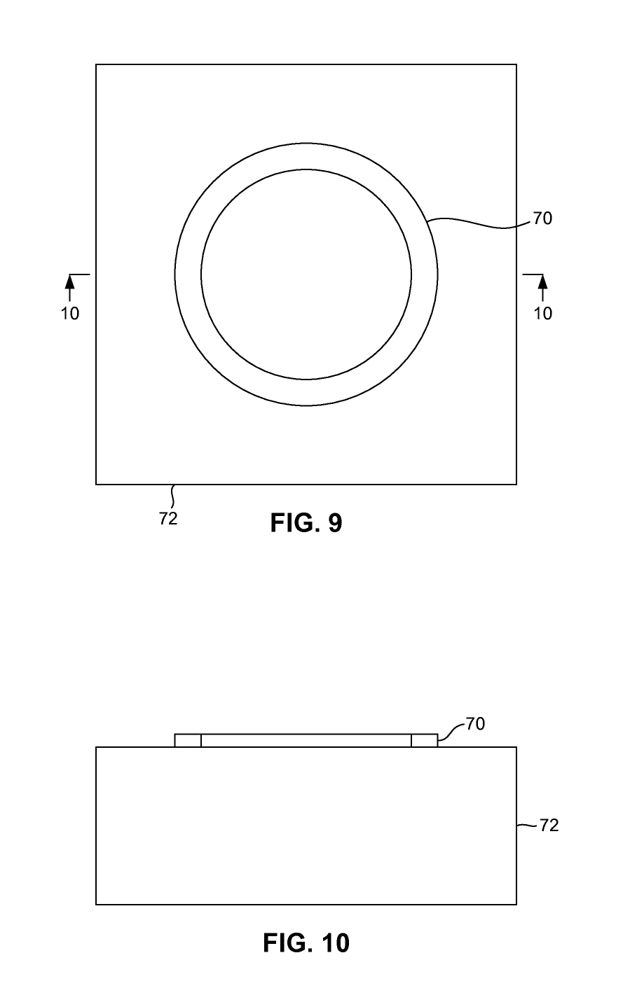

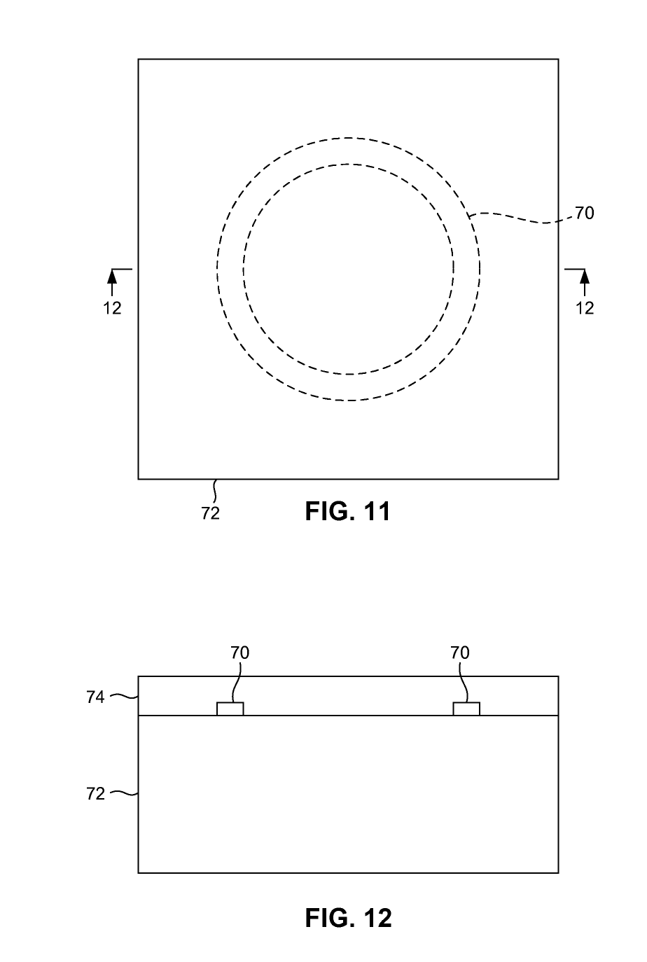

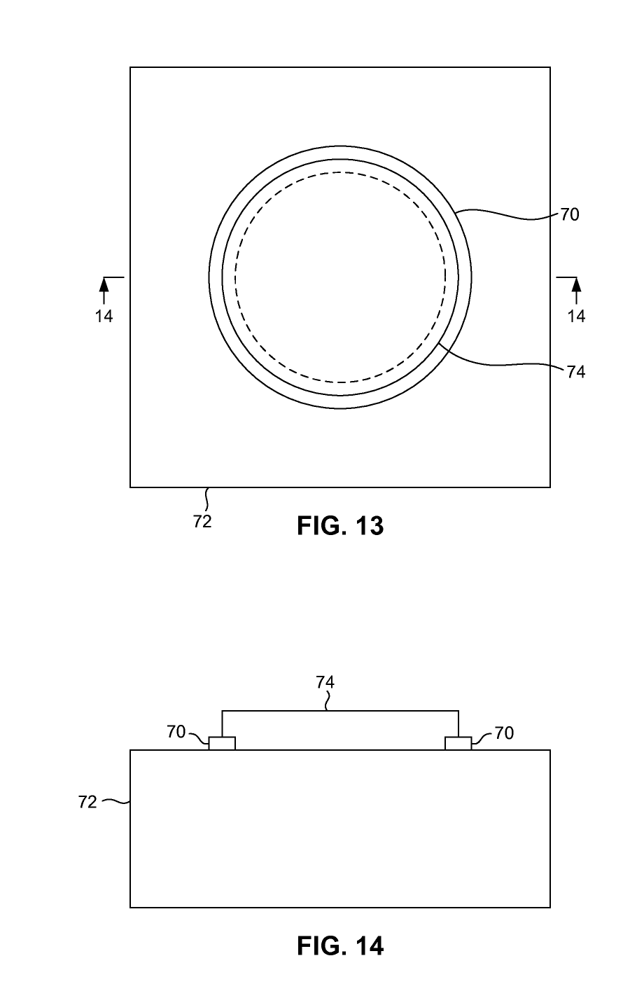

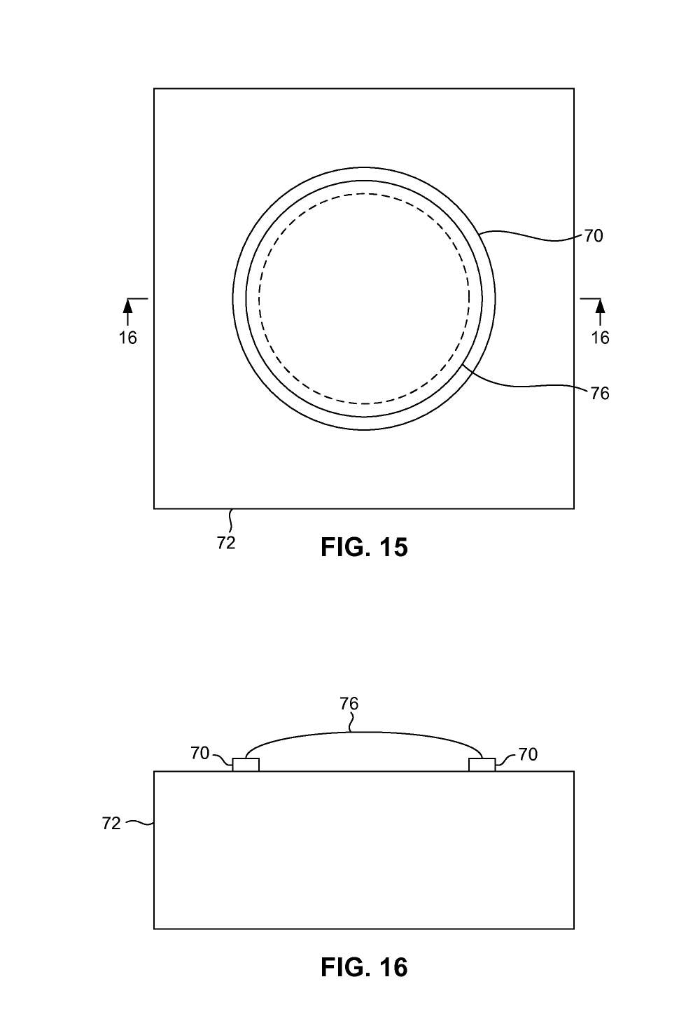

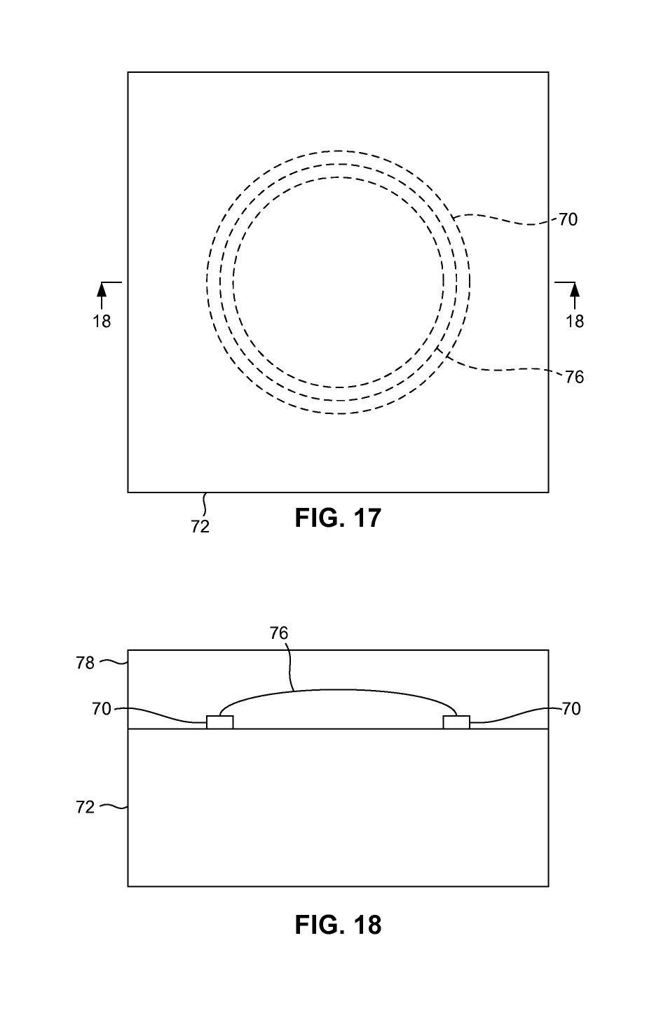

An exemplary method for making opto-electronic device 10 (FIGS. 1-2) is illustrated in FIGS. 9-29. As illustrated in FIGS. 9-10, a mask is first formed by applying a layer of opaque material such as chromium 70 to the surface of a transparent substrate such as glass 72. Chromium 70 is patterned in an annular shape. The chromium-on-glass structure can be formed in a conventional manner. As illustrated in FIGS. 11-12, a layer of positive photoresist 74, such as a product known as AZ9260 available from AZ Electronic Materials S.A. of Luxembourg, is then applied (e.g., by spin coating) over chromium 70. As illustrated in FIGS. 13-14, positive photoresist 74 is patterned into a disc shape having a diameter less than the outer diameter of chromium 70 and greater than the inner diameter of chromium 70. As illustrated in FIGS. 15-16, positive photoresist 74 is subjected to a reflow process, which shapes positive photoresist 74 into a convex lens 76. A suitable reflow process involves, for example, heating the photoresist up to 160 C and maintaining it at that temperature for two minutes. As illustrated in FIGS. 17-18, a second layer of positive photoresist 78 is applied over convex lens 76 and subjected to a soft bake.

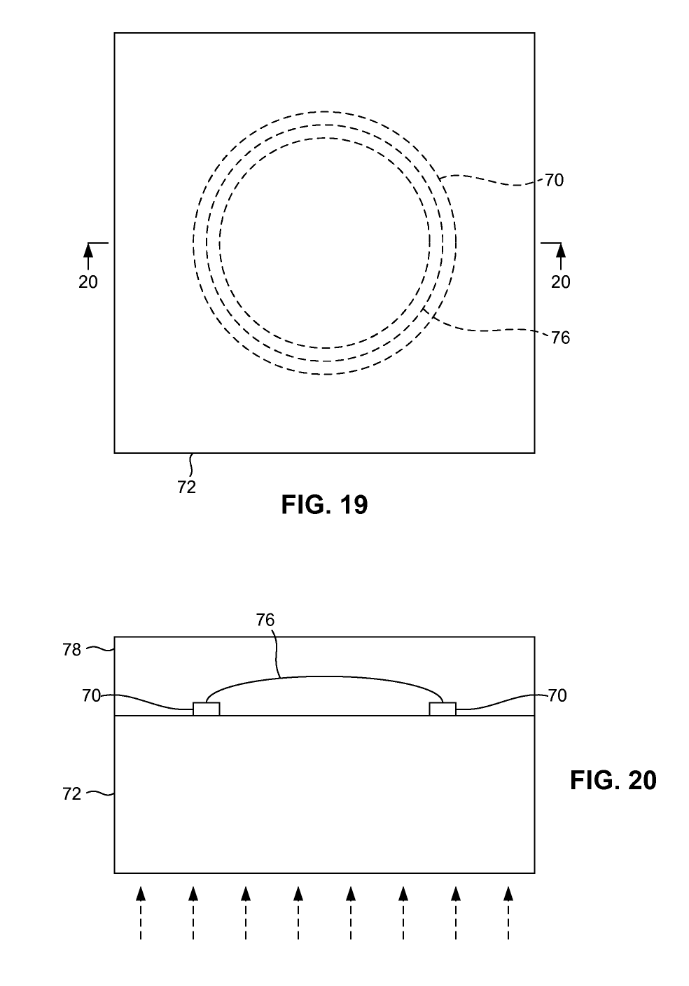

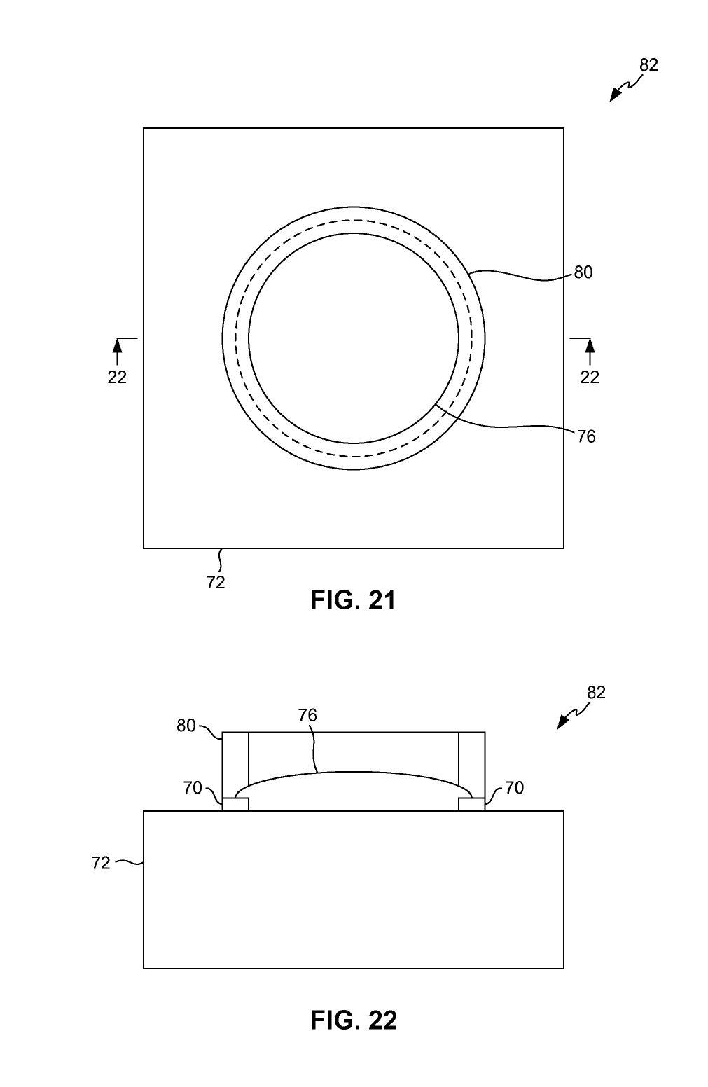

As illustrated in FIGS. 19-20, the assembly (FIG. 18) is illuminated from the back or bottom, as indicated by the broken-line arrows in FIG. 20. As illustrated in FIGS. 21-22, subsequent developing removes the portion of positive photoresist 78 that was illuminated and leaves intact the barrel-shaped portion 80 of positive photoresist 78 that was masked by chromium 70. The prior reflow step ensures that convex lens 76 is not developed away. The resulting mask assembly 82 is used as described below.

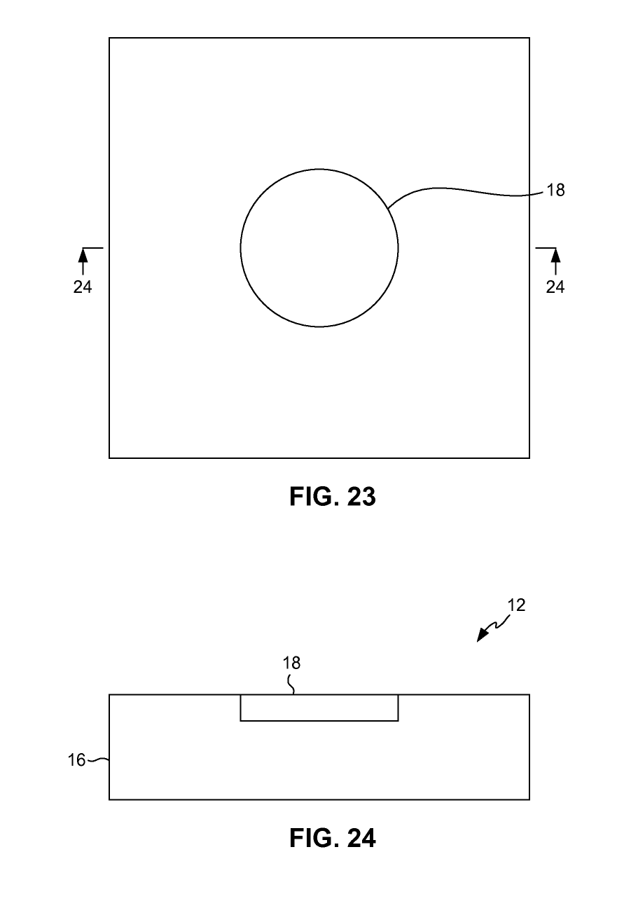

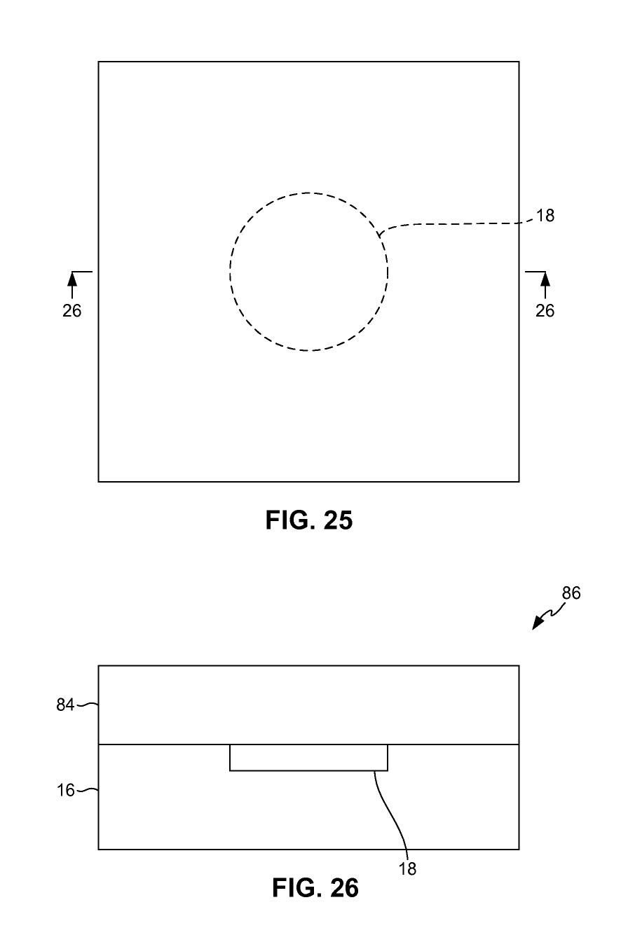

As illustrated in FIGS. 23-24, semiconductor device 12 (described above with regard to FIGS. 1-2) is provided. Semiconductor device 12 can comprise, for example, a PIN photodiode or other suitable photodetector. As illustrated in FIGS. 25-26, a layer of positive photoresist 84 is applied (e.g., by spin coating) to the surface of semiconductor device 12, covering active area 18 and surrounding areas. The resulting assembly 86 is used with the above-described mask assembly 82 (FIG. 22) in the following steps.

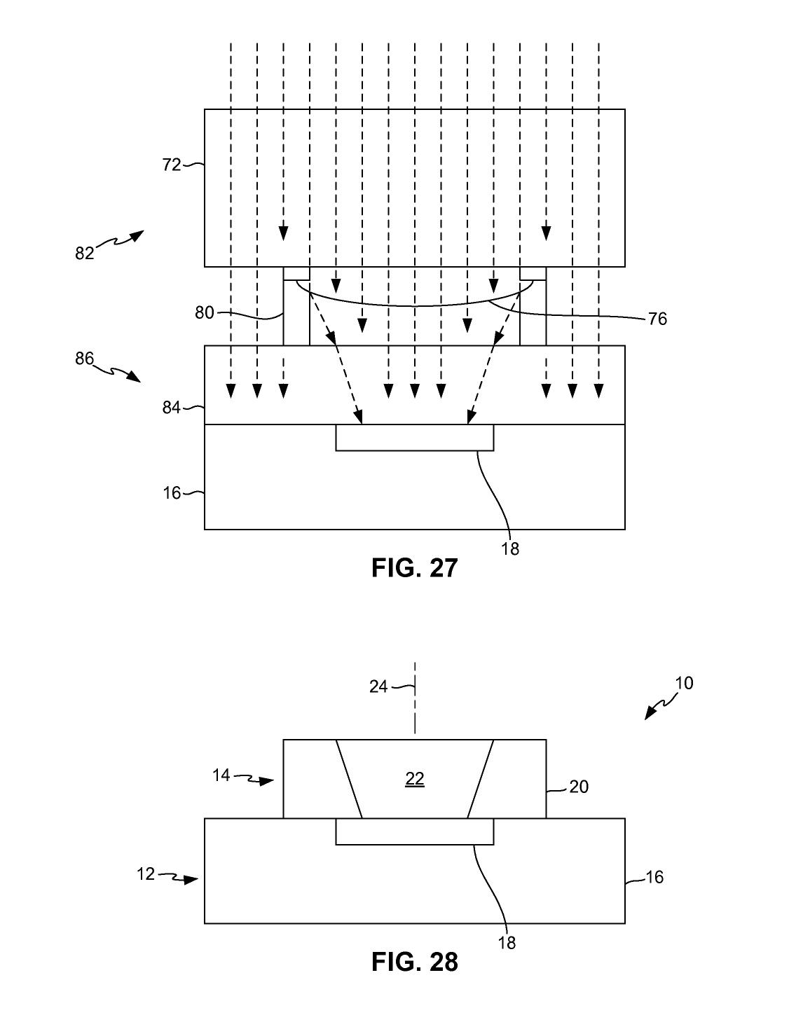

As illustrated in FIG. 27, mask assembly 82 is placed on top of assembly 86 and illuminated from the top, as indicated by the broken-line arrows in FIG. 27. Barrel-shaped portion 80 of mask assembly 82 serves as a standoff to ensure proper spacing. Note that the light is transmitted through all of glass 72 and through convex lens 76. Convex lens 76 bends or images the light into a cone shape, and refraction further narrows the cone of light as the light enters positive photoresist 84. Thus, a cone-shaped region within positive photoresist 84 is illuminated. Subsequent developing removes the portion of positive photoresist 84 that was illuminated and leaves intact the portion of positive photoresist 84 that not illuminated. The portion of positive photoresist 84 that was not illuminated defines body 20 of the resulting non-imaging optical concentrator 14 (FIG. 28). Removal of the portion of positive photoresist 84 that was illuminated defines cavity region 22 of the resulting non-imaging optical concentrator 14.

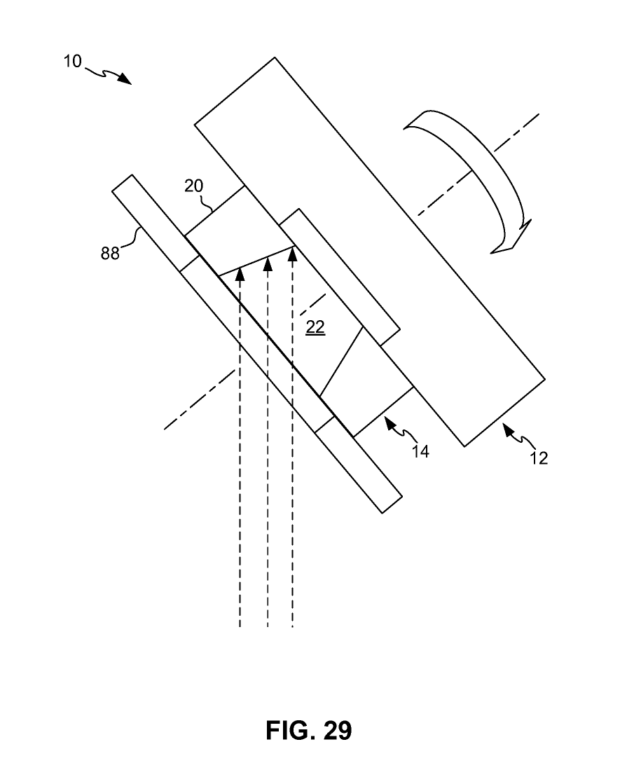

As illustrated in FIG. 29, a shadow mask 88 is placed on the top of body 20. The shadow mask opening is aligned with cavity region 22. The entire assembly comprising semiconductor device 12 and non-imaging optical concentrator 14 is rotated relative on an axis at an oblique angle to the direction of a source of metal in a metal deposition process, indicated by broken-line arrows. It is suitable for the deposition to be done by evaporation, where the metal is deposited in a line-of-sight from the source to the sidewalls of cavity region 22. An optically reflective metal, such as gold, is suitable. Shadow mask 88 masks active area 18 while allowing metal to be deposited on the sidewalls of cavity region 22. The metal is evenly deposited around the sidewalls of cavity region 22 as the assembly is rotated.

Although not shown, an alternative method for making opto-electronic device 10 includes providing a mold having a shape corresponding to non-imaging optical concentrator 14. The mold is filled with a light-curable infrared-transparent liquid and lowered onto the top of semiconductor device 12. The mold is then irradiated with ultraviolet light to cure the liquid material, thereby forming optical concentrator 14. The mold is removed, and metal is deposited on the sidewalls of cavity region 22 in the manner described above.

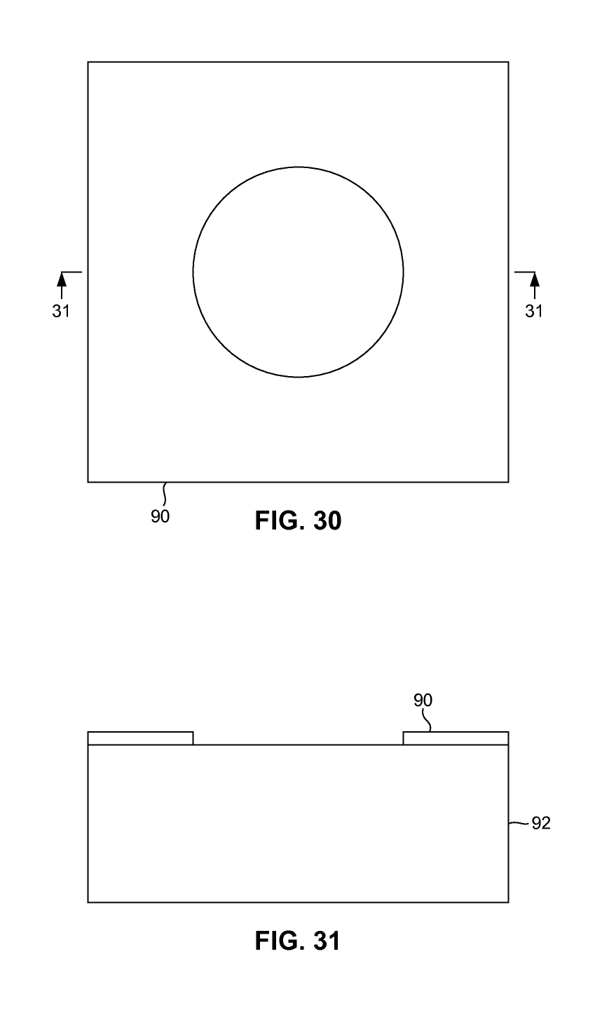

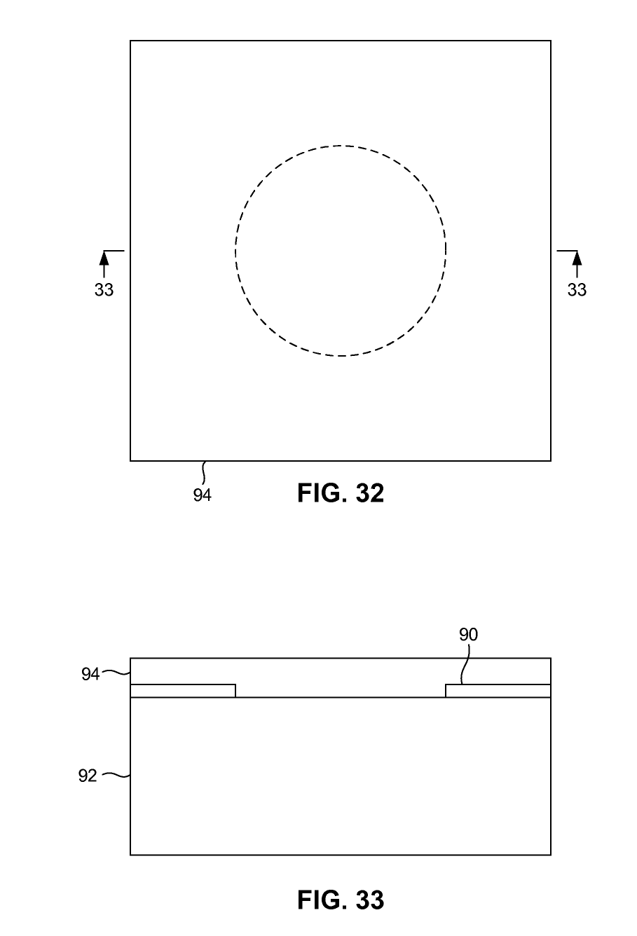

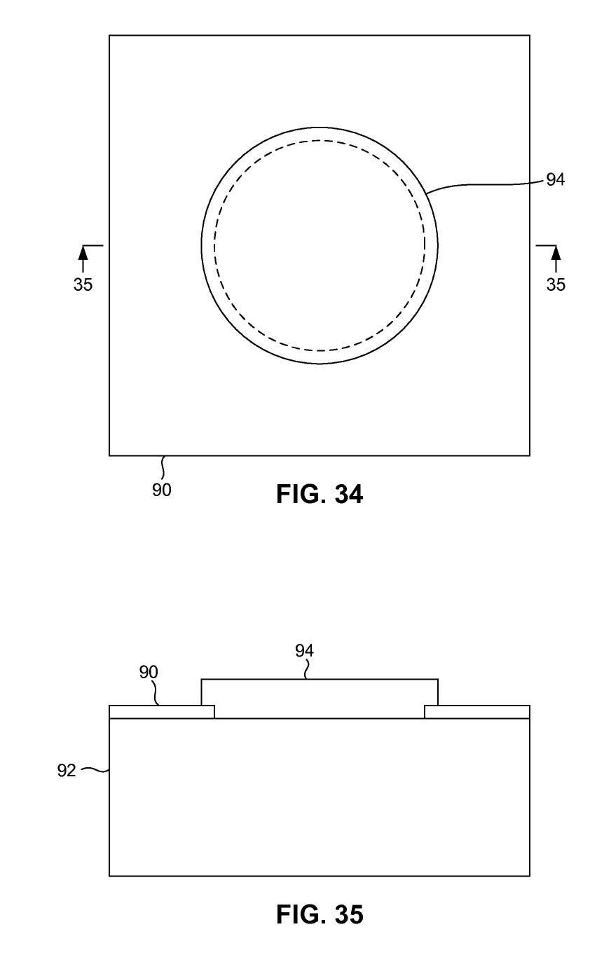

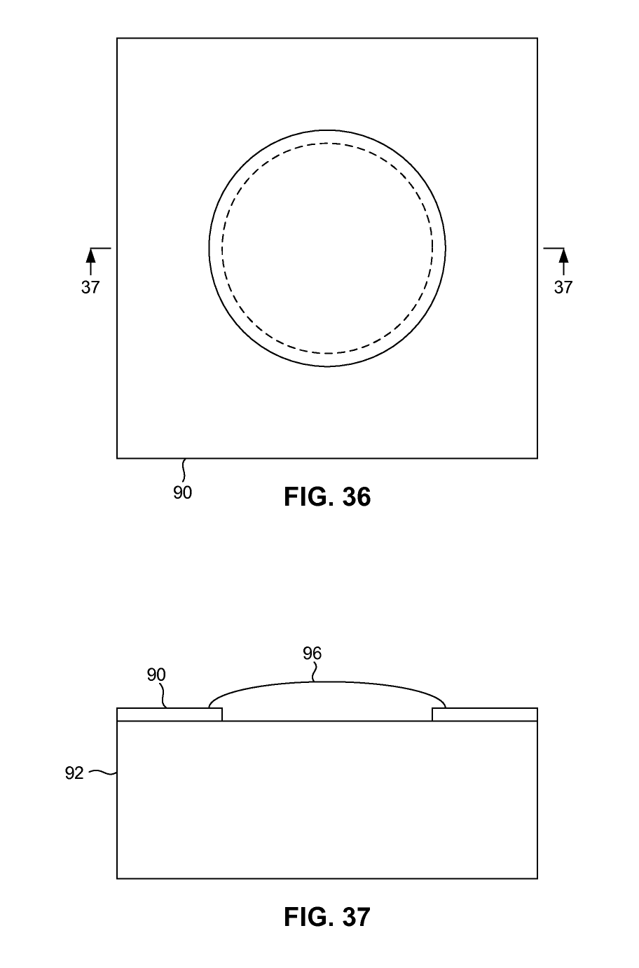

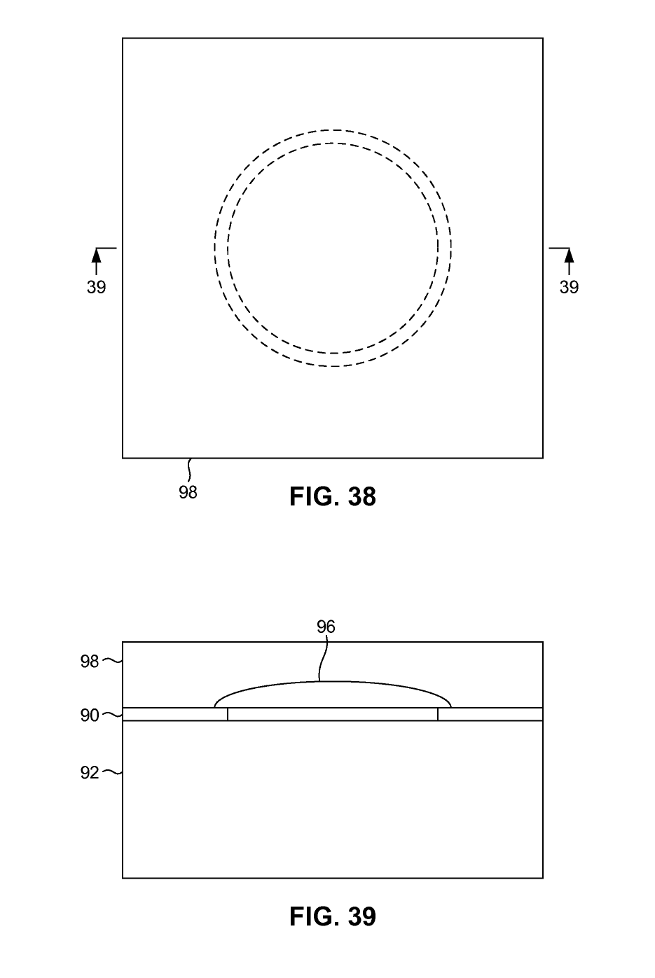

An exemplary method for making opto-electronic device 42 (FIGS. 5-6) is illustrated in FIGS. 30-49. As illustrated in FIGS. 30-31, a mask is first formed by applying a layer of opaque material such as chromium 90 to the surface of a transparent substrate such as glass 92. Chromium 90 is patterned in shape having a circular opening. As illustrated in FIGS. 32-33, a layer of positive photoresist 94 is then applied (e.g., by spin coating) over chromium 90. As illustrated in FIGS. 34-35, positive photoresist 94 is patterned into a disc shape having a diameter less than the outer diameter of the circular opening in chromium 90 and greater than the inner diameter of the circular opening in chromium 90. As illustrated in FIGS. 36-37, positive photoresist 94 is subjected to a reflow process, which shapes positive photoresist 94 into a convex lens 96. As illustrated in FIGS. 38-39, a second layer of positive photoresist 98 is applied over convex lens 96 and subjected to a soft bake.

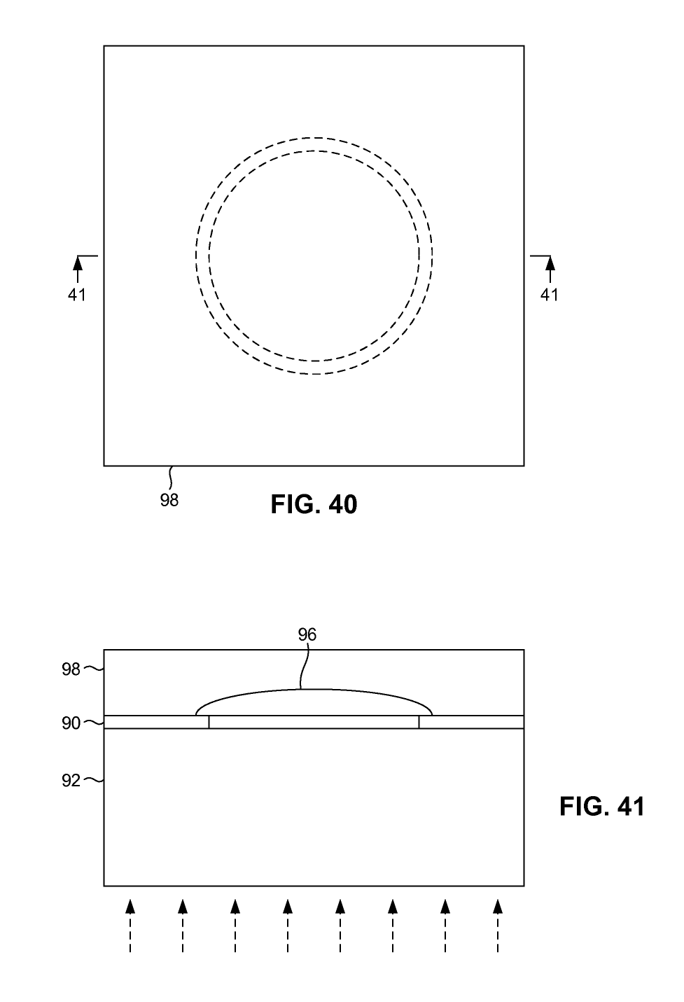

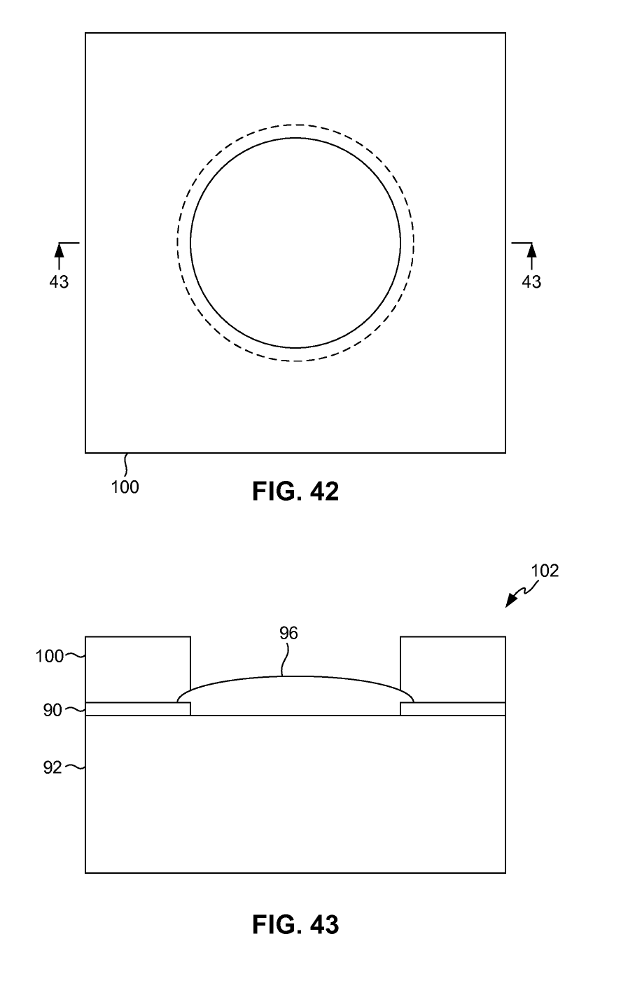

As illustrated in FIGS. 40-41, the assembly (FIG. 39) is illuminated from the back or bottom, as indicated by the broken-line arrows in FIG. 41. As illustrated in FIGS. 42-43, subsequent developing removes the portion of positive photoresist 98 that was illuminated and leaves intact a portion 100 of positive photoresist 78 that was masked by chromium 70. Portion 100 has a circular opening corresponding to the circular opening in chromium 90. The prior reflow step ensures that convex lens 96 is not developed away. The resulting mask assembly 102 is used as described below.

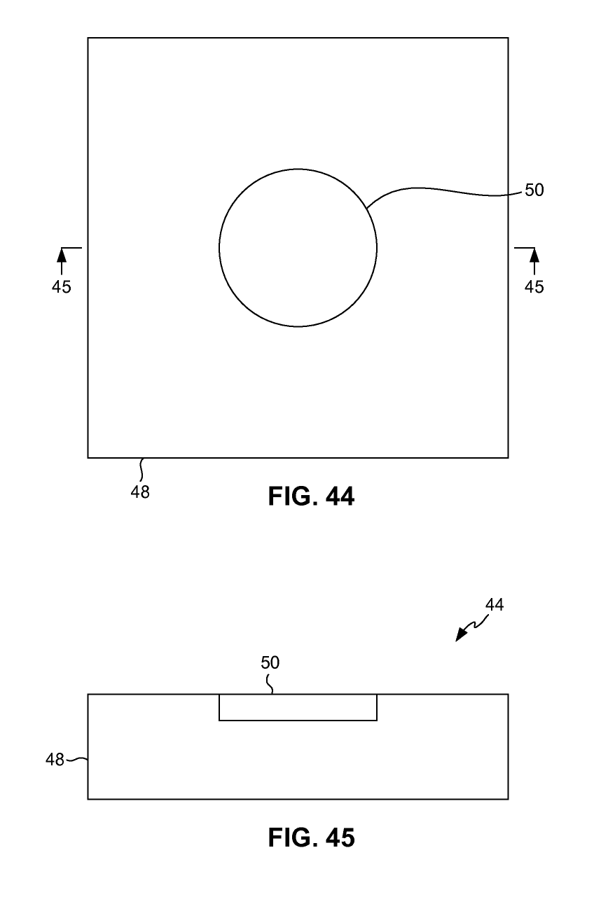

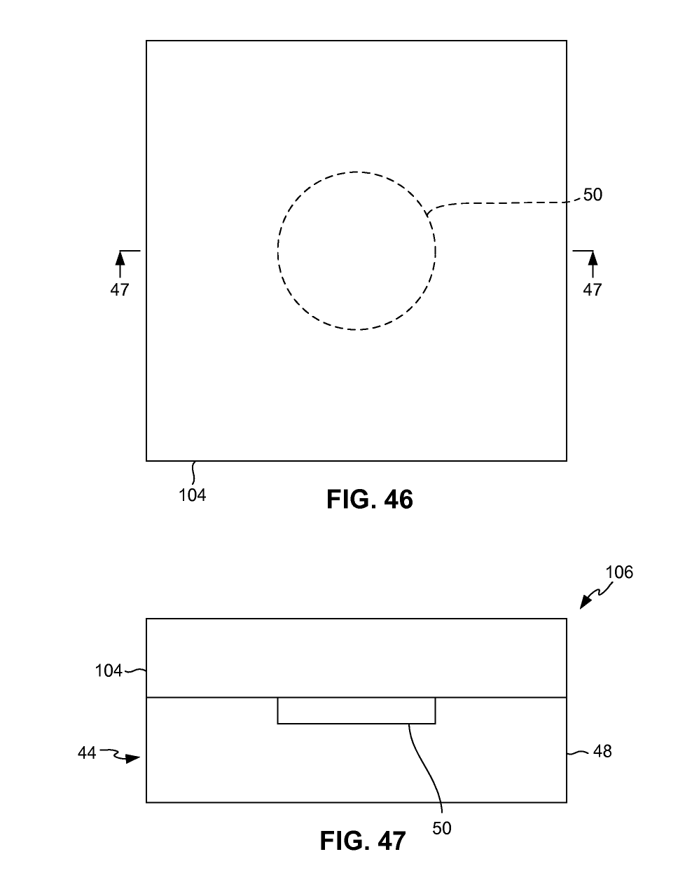

As illustrated in FIGS. 44-45, semiconductor device 44 (described above with regard to FIGS. 5-6) is provided. Semiconductor device 44 can comprise, for example, a PIN photodiode or other suitable photodetector. As illustrated in FIGS. 46-47, a layer of negative photoresist 104 is applied (e.g., by spin coating) to the surface of semiconductor device 44, covering active area 50 and surrounding areas. The resulting assembly 106 is used with the above-described mask assembly 102 (FIG. 43) in the following steps.

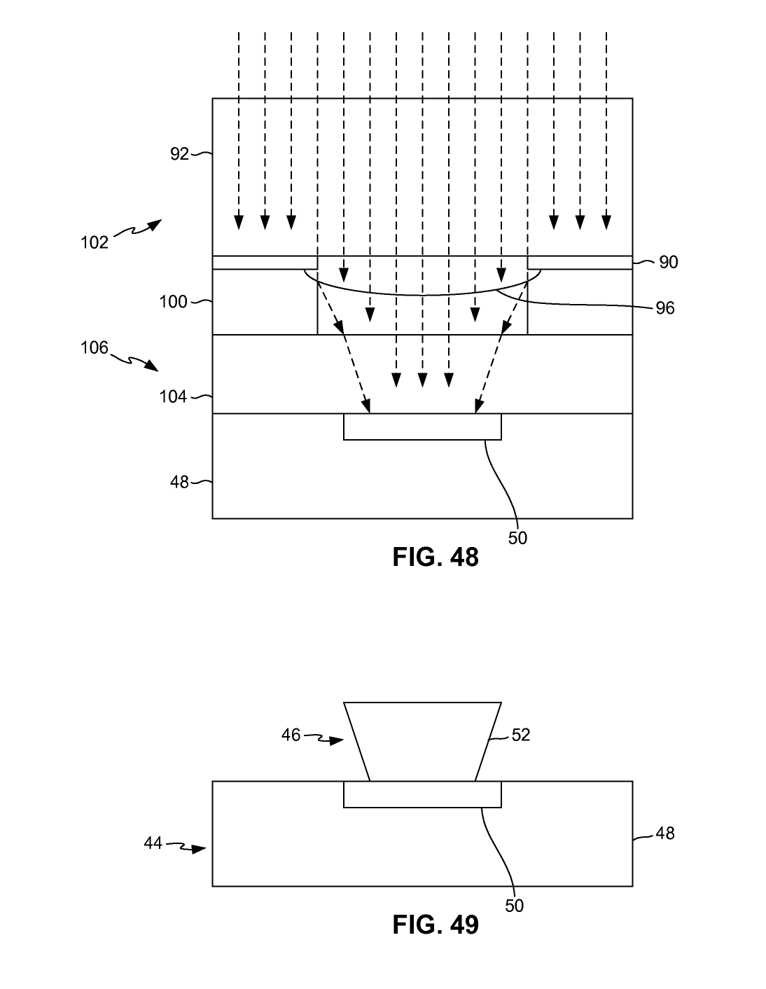

As illustrated in FIG. 48, mask assembly 102 is placed on top of assembly 106 and illuminated from the top, as indicated by the broken-line arrows in FIG. 48. Portion 100 of mask assembly 102 serves as a standoff to ensure proper spacing. Note that the light is transmitted through all of glass 92 and through convex lens 96. Convex lens 96 bends or images the light into a cone shape, and refraction further narrows the cone of light as the light enters negative photoresist 104. Thus, a cone-shaped region within negative photoresist 104 is illuminated. Subsequent developing removes the portion of negative photoresist 104 that was not illuminated and leaves intact the portion of negative photoresist 104 that illuminated. The portion of negative photoresist 104 that was illuminated defines solid region 52 of the resulting non-imaging optical concentrator 46 (FIG. 49).

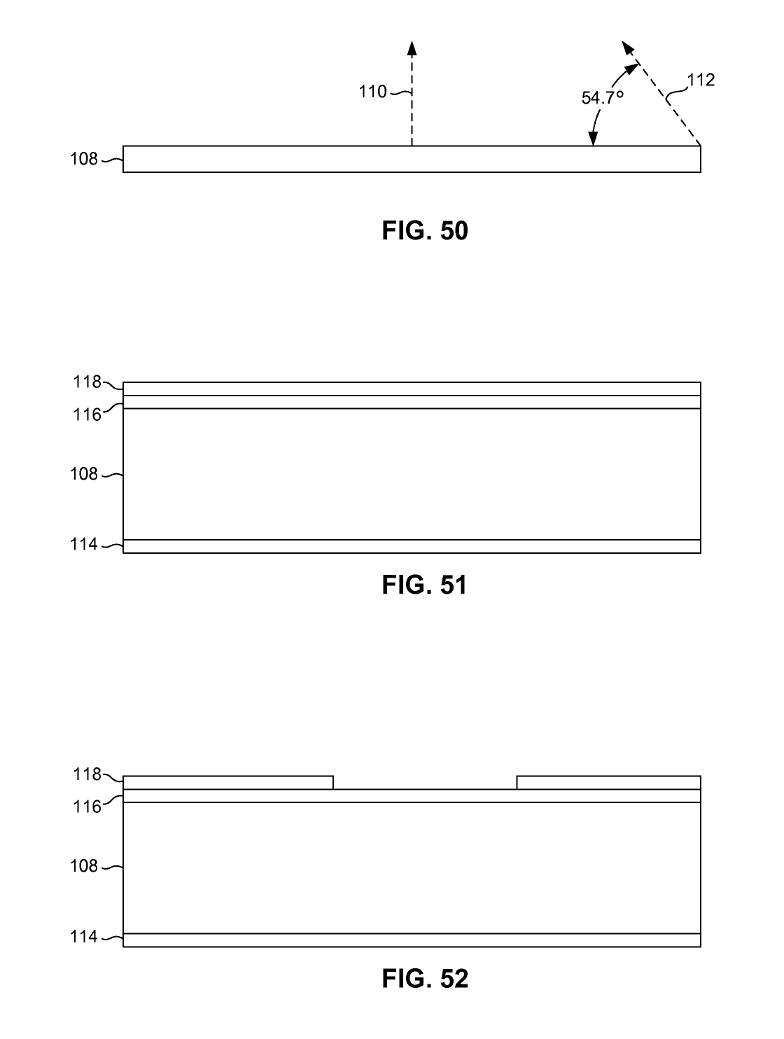

An exemplary method for making opto-electronic device 26 (FIGS. 3-4) is illustrated in FIGS. 50-55. The method involves a well-known technique called anisotropic etching. As illustrated in FIG. 50, a wafer of a suitable semiconductor material such as silicon 108 is provided. As the crystalline structure is important in this method, silicon 108 is preferably <100> silicon. The arrow 110 indicates the <100> direction, i.e., the direction normal to the <100> crystal plane. The <111> direction, indicated by the arrow 112, is also important in this method. Note that the angle between the <100> and <111> directions is 54.7 degrees. Silicon 108 should be cleaned (e.g., so-called “RCA clean”) prior to the remaining steps.

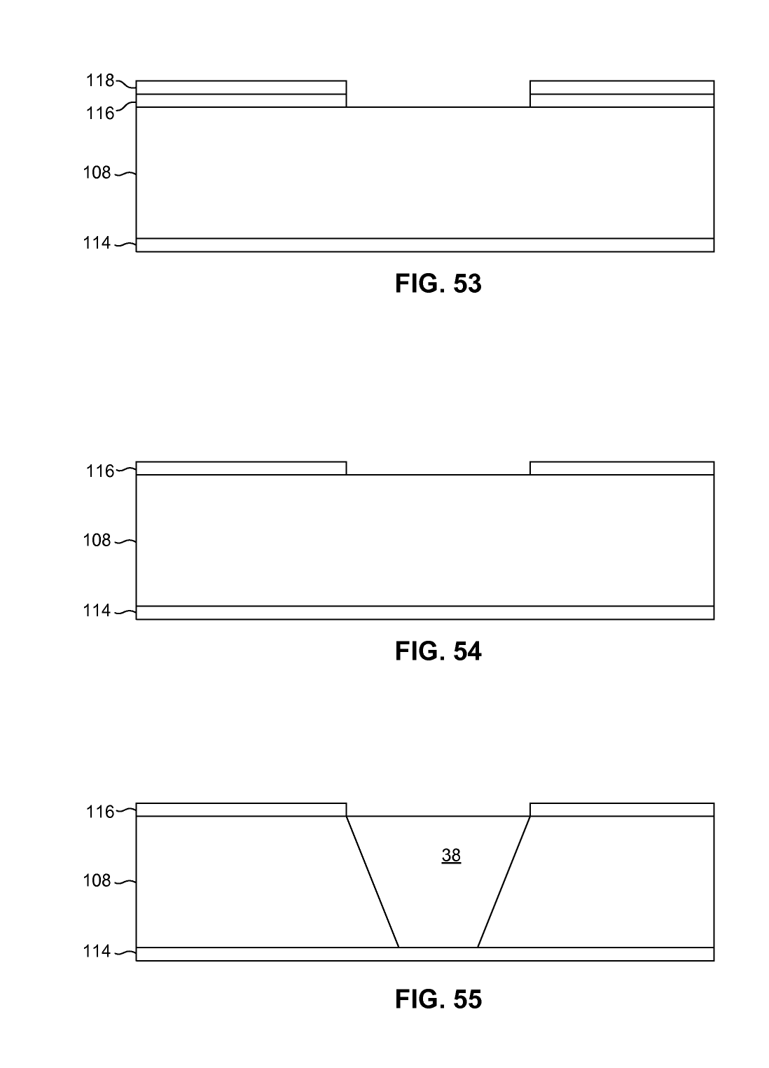

As illustrated in FIG. 51, silicon 108 can be subjected to thermal oxidation (e.g., about 900-1100 C) to create oxide layers 114 and 116 on the wafer surfaces. A layer of positive photoresist 118 is then applied (e.g., by spin coating) over oxide layer 116. As illustrated in FIG. 52, a circular opening is then formed in positive photoresist 118. As illustrated in FIG. 53, an oxide etch process is then performed to form a circular opening in oxide layer 116 corresponding to the circular opening in positive photoresist 118. During the oxide etch, the back or bottom side of the structure should be protected with photoresist or wax (not shown) or by placing the structure on a glass plate (not shown). Positive photoresist 118 is removed follwing the oxide etch. The resulting structure having a circular opening in oxide layer 116 is shown in FIG. 54.

The structure (FIG. 54) is then subjected to a potassium hydroxide (KOH) etch. It is well known that <100> silicon etches anisotropically, such that the etched area has walls oriented at a 54.7 degree angle from the <100> crystal plane. This occurs because KOH displays an etch rate selectivity roughly 400 times higher in <100> crystal directions than in <111> crystal directions. As a result of such KOH etching, the above-described four-sided pyramid-shaped cavity region 38 is formed in silicon 108.

Oxide layers 114 and 116 are then removed (e.g., by buffered hydrofluoric acid (BHF)). Optically reflective metal is then deposited on the sidewalls of cavity 38 (FIG. 55) on the wafer by sputtering or evaporation. The resulting structure is cut to the proper size and mounted on semiconductor device 28 to form the opto-electronic device 26 shown in FIGS. 3-4. As the above-described process is well understood by persons skilled in the art, details have been omitted for clarity.

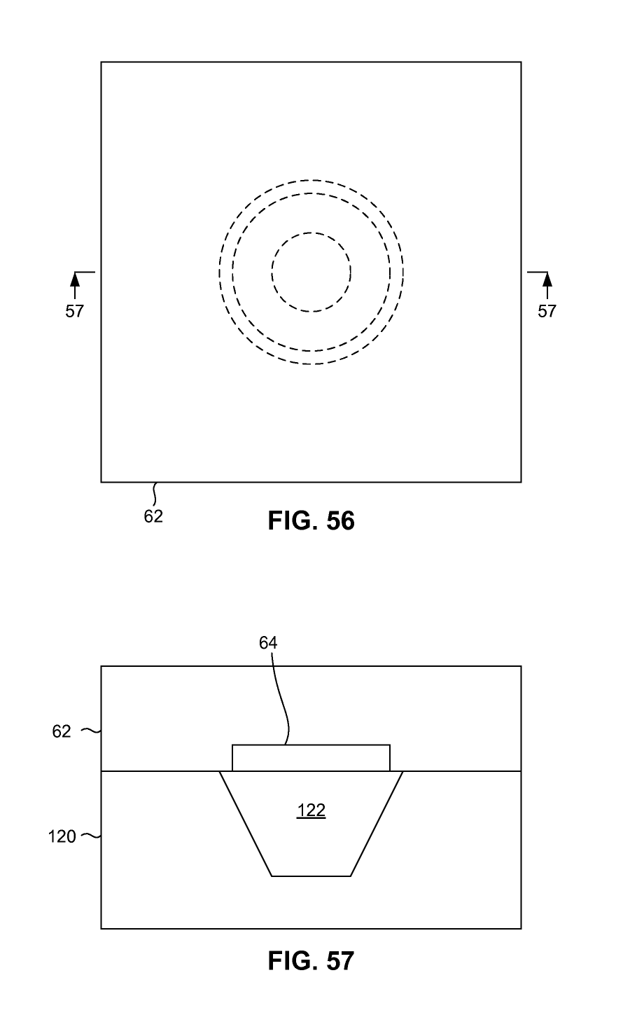

An exemplary method for making opto-electronic device 56 (FIGS. 7-8) is illustrated in FIGS. 56-57. A mold 120 is provided. Mold 120 is transparent to ultraviolet light with the exception of the top surface of mold 120, which is opaque to ultraviolet light. Mold 120 has a mold cavity 122 with a shape corresponding to non-imaging optical concentrator 60. Mold cavity 122 is filled with a light-curable liquid (not shown), and semiconductor device 58 is lowered onto mold 120 such that the surface of semiconductor device 58 contacts the surface of the pool of liquid in mold cavity 122. Alternatively, mold 120 can be lowered onto semiconductor device 58, as capillary action inhibits the liquid from falling out of mold cavity 122. Mold 120 is irradiated with ultraviolet light to cure the liquid material within mold cavity 122, thereby forming non-imaging optical concentrator 60 (FIGS. 7-8) on the surface of semiconductor device 58. Mold 120 is then removed.

It should be understood that although making a single opto-electronic device is described above for purposes of clarity, many such opto-electronic devices can be formed simultaneously on the same wafer.

One or more illustrative embodiments of the invention have been described above. However, it is to be understood that the invention is defined by the appended claims and is not limited to the specific embodiments described.

What is claimed is:

1. An opto-electronic device, comprising:
a semiconductor device having a substrate and a photodetector formed on a surface of the substrate, the photodetector having an active area; and
a non-imaging optical concentrator on a surface of the semiconductor device, the non-imaging optical concentrator having a peripheral surface extending around a central region of the active area and redirecting at least a portion of incoming light into the active area.

2. The opto-electronic device of claim 1, wherein the peripheral surface has a tapering cross sectional shape.

3. The opto-electronic device of claim 2, wherein the peripheral surface has a circular cross-sectional shape.

4. The opto-electronic device of claim 3, wherein the non-imaging optical concentrator has a frusto-conical cavity region defining the peripheral surface, the cavity region having a wider end farther from the active area with respect to a direction parallel to an optical axis of the active area than a narrower end adjacent the active area, and the peripheral surface reflects light entering the cavity region at the wider end of the cavity region toward the active area.

5. The opto-electronic device of claim 4, wherein the peripheral surface comprises a metal film in the cavity region.

6. The opto-electronic device of claim 3, wherein the non-imaging optical concentrator has a frusto-conical solid region defining the peripheral surface, the solid region having a wider end farther from the active area with respect to a direction parallel to an optical axis of the active area than a narrower end adjacent the active area, and the peripheral surface reflects light entering the solid region at a wider end of the solid region toward the active area.

7. The opto-electronic device of claim 3, wherein the non-imaging optical concentrator has a frusto-conical solid region defining the peripheral surface, the solid region having a narrower end farther from the active area with respect to a direction parallel to an optical axis of the active area than a wider end adjacent the active area, and the peripheral surface refracts light entering the solid region through the peripheral surface toward the active area.

8. The device of claim 2, wherein the peripheral surface has a polygonal cross-sectional shape.

9. The opto-electronic device of claim 8, wherein the non-imaging optical concentrator has a frusto-polyhedral cavity region defining the peripheral surface, the cavity region having a wider end farther from the active area with respect to a direction parallel to an optical axis of the active area than a narrower end adjacent the active area, and the peripheral surface reflects light entering the cavity region at a wider end of the cavity region toward the active area.

10. The opto-electronic device of claim 9, wherein the peripheral surface comprises a metal film in the cavity region.

11. The opto-electronic device of claim 9, wherein the peripheral surface has a square cross-sectional shape.

12. A method of operation in an opto-electronic device, the opto-electronic device comprising a semiconductor device and a non-imaging optical concentrator on a surface of the semiconductor device, the non-imaging optical concentrator having a peripheral surface extending around a central region of the active area the method comprising:
the non-imaging optical concentrator receiving incoming light; and
the peripheral surface of the non-imaging optical concentrator redirecting at least a portion of the incoming light into an active area of a photodetector formed on a surface of a substrate of the semiconductor device.

13. The method of claim 12, wherein the peripheral surface has a tapering cross sectional shape.

14. The method of claim 13, wherein the peripheral surface has a circular cross-sectional shape.

15. The method of claim 14, wherein the non-imaging optical concentrator has a frusto-conical cavity region defining the peripheral surface, the cavity region having a wider end farther from the active area with respect to a direction parallel to an optical axis of the active area than a narrower end adjacent the active area, and the peripheral surface reflects light entering the cavity region at the wider end of the cavity region toward the active area.

16. The method of claim 15, wherein the peripheral surface comprises a metal film in the cavity region.

17. The method of claim 14, wherein the non-imaging optical concentrator has a frusto-conical solid region defining the peripheral surface, the solid region having a wider end farther from the active area with respect to a direction parallel to an optical axis of the active area than a narrower end adjacent the active area, and the peripheral surface reflects light entering the solid region at a wider end of the solid region toward the active area.

18. The method of claim 14, wherein the non-imaging optical concentrator has a frusto-conical solid region defining the peripheral surface, the solid region having a narrower end farther from the active area with respect to a direction parallel to an optical axis of the active area than a wider end adjacent the active area, and the peripheral surface refracts light entering the solid region through the peripheral surface toward the active area.

19. The method of claim 13, wherein the peripheral surface has a polygonal cross-sectional shape.

20. The method of claim 19, wherein the non-imaging optical concentrator has a frusto-polyhedral cavity region defining the peripheral surface, the cavity region having a wider end farther from the active area with respect to a direction parallel to an optical axis of the active area than a narrower end adjacent the active area, and the peripheral surface reflects light entering the cavity region at a wider end of the cavity region toward the active area.
